(19) United States
(12) Patent Application Publication
(10) Pub. No.: US 2023/0361203 A1
(43) Pub. Date: Nov. 9, 2023

(54) FINFET ISOLATION DEVICE AND METHOD

(71) Applicant: Micron Technology, Inc., Boise, ID (US)

(72) Inventors: Neng-Kuo Chen, Boise, ID (US); Jun Zhao, Meridian, ID (US); Andrew Dennis Carswell, Boise, ID (US)

(21) Appl. No.: 17/738,521

(22) Filed: May 6, 2022

(51) Int. Cl. H01L 29/66; H01L 21/8234; H01L 27/088

(52) U.S. Cl. CPC H01L 29/6681; H01L 29/66545; H01L 21/823431; H01L 21/823481; H01L 27/0886

(57) ABSTRACT

Apparatus and methods are disclosed, including transistors, memory devices and systems. Example transistors, memory devices, systems and methods include an inter-gate dielectric structure between adjacent gates, wherein the inter-gate dielectric structure includes a first dielectric material adjacent a fin channel, and a second dielectric material different from the first dielectric material located over the first dielectric material.

### BACKGROUND

Memory devices are semiconductor circuits that provide electronic storage of data for a host system (e.g., a computer or other electronic device). Memory devices may be volatile or non-volatile. Volatile memory requires power to maintain data, and includes devices such as random-access memory (RAM), static random-access memory (SRAM), dynamic random-access memory (DRAM), or synchronous dynamic random-access memory (SDRAM), among others. Non-volatile memory can retain stored data when not powered, and includes devices such as flash memory, read-only memory (ROM), electrically erasable programmable ROM (EEPROM), erasable programmable ROM (EPROM), resistance variable memory, such as phase change random access memory (PCRAM), resistive random-access memory (RRAM), or magnetoresistive random access memory (MRAM), among others.

Host systems typically include a host processor, a first amount of main memory (e.g., often volatile memory, such as DRAM) to support the host processor, and one or more storage systems (e.g., often non-volatile memory, such as flash memory) that provide additional storage to retain data in addition to or separate from the main memory.

A storage system, such as a solid-state drive (SSD), can include a memory controller and one or more memory devices, including a number of dies or logical units (LUNs). In certain examples, each die can include a number of memory arrays and peripheral circuitry thereon, such as die logic or a die processor. The memory controller can include interface circuitry configured to communicate with a host device (e.g., the host processor or interface circuitry) through a communication interface (e.g., a bidirectional parallel or serial communication interface).

The present description relates generally to example structures and methods for FinFET transistors and isolation structures between fins.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1 illustrates a memory device in accordance with some example embodiments.

FIG. 2 illustrates a FinFET transistor in accordance with some example embodiments.

FIG. 3A illustrates a stage of manufacture of a FinFET transistor in accordance with some example embodiments.

FIG. 3B illustrates a stage of manufacture of a FinFET transistor in accordance with some example embodiments.

FIG. 3C illustrates a stage of manufacture of a FinFET transistor in accordance with some example embodiments.

FIG. 4A illustrates a stage of manufacture of a FinFET transistor in accordance with some example embodiments.

FIG. 4B illustrates a stage of manufacture of a FinFET transistor in accordance with some example embodiments.

FIG. 4C illustrates a stage of manufacture of a FinFET transistor in accordance with some example embodiments.

FIG. 4D illustrates diagram of a cross section of a FinFET transistor in accordance with some example embodiments.

FIG. 5A illustrates a stage of manufacture of a FinFET transistor in accordance with some example embodiments.

FIG. 5B illustrates a stage of manufacture of a FinFET transistor in accordance with some example embodiments.

FIG. 5C illustrates diagram of a cross section of a FinFET transistor in accordance with some example embodiments.

FIG. 6 illustrates an example method flow diagram in accordance with other example embodiments.

FIG. 7 illustrates an example block diagram of a computing system in accordance with some example embodiments.

### DETAILED DESCRIPTION

The following description and the drawings sufficiently illustrate specific embodiments to enable those skilled in the art to practice them. Other embodiments may incorporate structural, logical, electrical, process, and other changes. Portions and features of some embodiments may be included in, or substituted for, those of other embodiments. Embodiments set forth in the claims encompass all available equivalents of those claims.

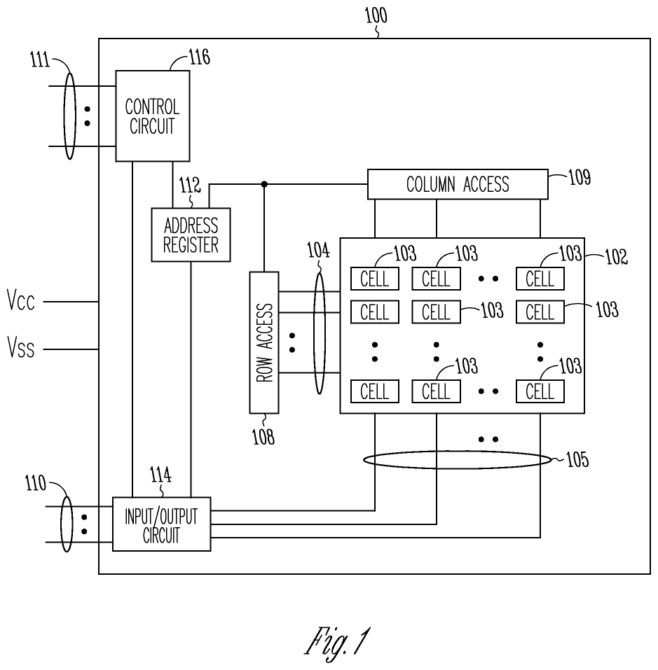

FIG. 1 shows a block diagram of an apparatus in the form of a memory device 100, according to an embodiment of the invention. Memory device 100 can include a memory array 102 having memory cells 103 that can be arranged in rows and columns along with lines (e.g., access lines) 104 and lines (e.g., data lines) 105. Memory device 100 can use lines 104 to access memory cells 103 and lines 105 to exchange information with memory cells 103. Memory cells 103 may include FinFET transistors as described in more detail below.

Row access 108 and column access 109 circuitry can respond to an address register 112 to access memory cells 103 based on row address and column address signals on lines 110, 111, or both. A data input/output circuit 114 can be configured to exchange information between memory cells 103 and lines 110. Lines 110 and 111 can include nodes within memory device 100 or pins (or solder balls) on a package where memory device 100 can reside.

A control circuit 116 can control operations of memory device 100 based on signals present on lines 110 and 111. A device (e.g., a processor or a memory controller) external to memory device 100 can send different commands (e.g., read, write, or erase commands) to memory device 100 using different combinations of signals on lines 110, 111, or both.

Memory device 100 can respond to commands to perform memory operations on memory cells 103, such as performing a read operation to read information from memory cells 103 or performing a write (e.g., programming) operation to store (e.g., program) information into memory cells 103. Memory device 100 can also perform an erase operation to clear information from some or all of memory cells 103.

Memory device 100 can receive a supply voltage, including supply voltages Vcc and Vss. Supply voltage Vss can operate at a ground potential (e.g., having a value of approximately zero volts). Supply voltage Vcc can include an external voltage supplied to memory device 100 from an external power source such as a battery or an alternating-current to direct-current (AC-DC) converter circuitry.

Each of memory cells 103 can be programmed to store information representing a value of a fraction of a bit, a value of a single bit, or a value of multiple bits such as two, three, four, or another number of bits. For example, each of memory cells 103 can be programmed to store information representing a binary value “0” or “1” of a single bit. The single bit per cell is sometimes called a single level cell. In another example, each of memory cells 103 can be programmed to store information representing a value for multiple bits, such as one of four possible values “00,” “01,” “10,” and “11” of two bits, one of eight possible values “000,” “001,” “010,” “011,” “100,” “101,” “110,” and “111” of three bits, or one of other values of another number of multiple bits. A cell that has the ability to store multiple bits is sometimes called a multi-level cell (or multi-state cell).

Memory device 100 can include a non-volatile memory device, and memory cells 103 can include non-volatile memory cells, such that memory cells 103 can retain information stored thereon when power (e.g., Vcc, Vss, or both) is disconnected from memory device 100. For example, memory device 100 can be a flash memory device, such as a NAND flash or a NOR flash memory device, or another kind of memory device, such as a variable resistance memory device (e.g., a phase change or resistive RAM device).

Memory device 100 can include a memory device where memory cells 103 can be physically located in multiple levels on the same device, such that some of memory cells 103 can be stacked over some other memory cells 103 in multiple levels over a substrate (e.g., a semiconductor substrate) of memory device 100.

One of ordinary skill in the art may recognize that memory device 100 may include other elements, several of which are not shown in FIG. 1, so as not to obscure the example embodiments described herein.

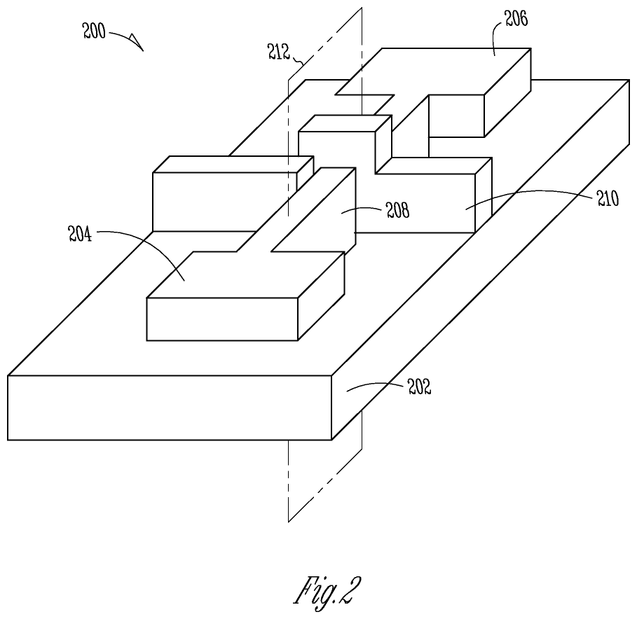

FIG. 2 shows a FinFET transistor 200 according to one example. The transistor 200 includes a source region 204, and a drain region 206 formed on a semiconductor substrate 202. A fin channel 208 is located between the source region 204, and the drain region 206, and a gate 210 is located over a portion of the fin channel 208. In operation, varying a charge on the gate 210 changes a conduction condition of the fin channel 208 and operates the transistor 200.

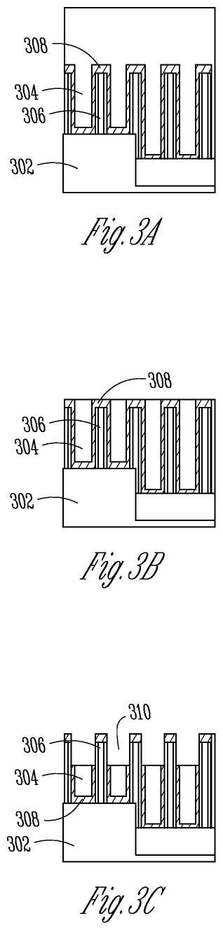

FIGS. 3A-3C show selected stages of manufacturing of a FinFET transistor according to one example. FIGS. 3A-3C mainly show manufacture of one or more gates over a fin channel. Manufacture of other transistor elements is omitted to focus on gate manufacture. FIG. 3A shows a cross section of a fin channel 302. Although not drawn to scale, and example cross section of plane 212 from FIG. 2 illustrates the view shown in FIGS. 3A-3C.

A number of dummy gates 306 are shown over the fin channel 302. In one example, the number of dummy gates 306 includes polysilicon dummy gates, although the invention is not so limited. A nitride layer 308 is formed over the number of dummy gates 306 and between the number of dummy gates 306. In the example shown, the nitride layer 308 is a conformal layer and includes a substantially consistent layer thickness, although variations may exist due to the fin channel 302 and dummy gate 306 topography. In one example the nitride layer includes silicon nitride, although the invention is not so limited.

An inter-gate dielectric structure is shown between adjacent dummy gates 306. FIG. 3A shows a first dielectric material 304 that is formed adjacent the fin channel 302 and between adjacent dummy gates 306. In one example, the first dielectric material 304 includes an oxide. In one example, the first dielectric material 304 includes silicon dioxide. In one example, the first dielectric material 304 includes silicon dioxide formed by a spin-on-glass (SOG) deposition operation. One of ordinary skill in the art, having the benefit of the present disclosure, will recognize that SOG oxide has a distinctive physical structure that is detectable upon cross section of a device.

FIG. 3B shows another stage of manufacture of a FinFET transistor subsequent to FIG. 3A. In FIG. 3B, the first dielectric material 304 has been planarized to a top level of the nitride layer 308 covering the number of dummy gates 306. One example of planarization includes chemical mechanical polishing (CMP) although the invention is not so limited.

FIG. 3C shows another stage of manufacture of a FinFET transistor subsequent to FIG. 3B. In FIG. 3C, an amount of the first dielectric material 304 is removed to form cavities 310. In one example the amount of the first dielectric material 304 is removed by etching, although other techniques may also be used to form the cavities 310. In the example of FIG. 3C, some of the nitride layer 308 is also removed from around the dummy gates 306. In some examples none of the nitride layer 308 is removed, and is some examples, only some of the nitride layer 308 is removed.

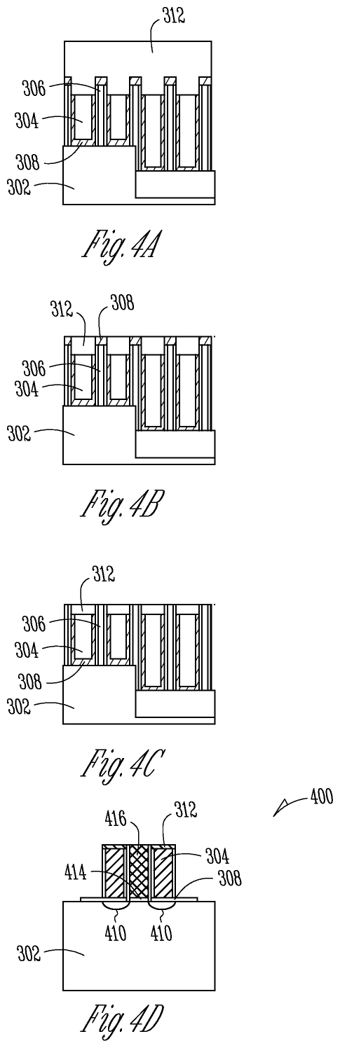

FIGS. 4A-4C show selected stages of manufacturing of a FinFET transistor that follow the stages of manufacturing shown in FIGS. 3A-3C in one example. In FIG. 4A, a second dielectric material 312 different from the first dielectric material 304 is located within the cavities 310, over the first dielectric material 304. In one example, the second dielectric material 312 includes an oxide. In one example, the second dielectric material 312 includes silicon dioxide. In one example, the second dielectric material 312 includes silicon dioxide formed by a high-density plasma deposition process. Although in selected examples, both the first dielectric material 304 and the second dielectric material 312 are both oxide materials, the invention is not so limited. In one example the dielectric materials 304, 312 are different chemistries. In one example the dielectric materials 304, 312 are the same chemistry, but with different detectable physical structures. One example of dielectric materials 304, 312 with the same or similar chemistry but different physical structure includes silicon oxide deposited by SOG, and silicon oxide deposited by high-density plasma deposition. The high-density plasma deposited silicon oxide will be detectably more dense that SOG deposited silicon oxide. As a result, high-density plasma deposited silicon oxide will be more resilient during subsequent operations, and may resist dishing during a planarization operation.

FIG. 4B shows another stage of manufacture of a FinFET transistor subsequent to FIG. 4A. In FIG. 4B, the second dielectric material 312 has been planarized to a top level of the nitride layer 308 covering the number of dummy gates 306. One example of planarization includes chemical mechanical polishing (CMP) although the invention is not so limited. In one example, the planarization in FIG. 4B is performed to stop on a remaining portion of the nitride layer 308 over the dummy gates 306.

FIG. 4C shows another stage of manufacture of a FinFET transistor subsequent to FIG. 4B. In FIG. 4C, the second dielectric material 312 has been further planarized to remove the nitride layer 308 and expose the dummy gates 306. One example of planarization includes chemical mechanical polishing (CMP) although the invention is not so limited. In one example, the planarization in FIG. 4C is performed to stop on polysilicon from the dummy gates 306.

FIG. 4D shows a FinFET transistor 400 according to one example as formed by the manufacture stages illustrated in FIGS. 4A-4C. The polysilicon dummy gates 306 have been removed, and replaced by conductive gates 416 such as metal gates. The gates 416 are located over the fin channel 302, and are separated from the fin channel by a gate dielectric 414. A pair of source/drain regions 410 are formed on either side of the gate 416.

In one example, planarizing can cause unwanted dishing in an inter-gate dielectric between adjacent gates 416 when only a low quality dielectric material is used. By adding a second, higher quality dielectric material 312 over the first dielectric material 304, dishing is reduced or eliminated. This helps to reduce or eliminate unwanted metal deposition that may cause electrical shorts.

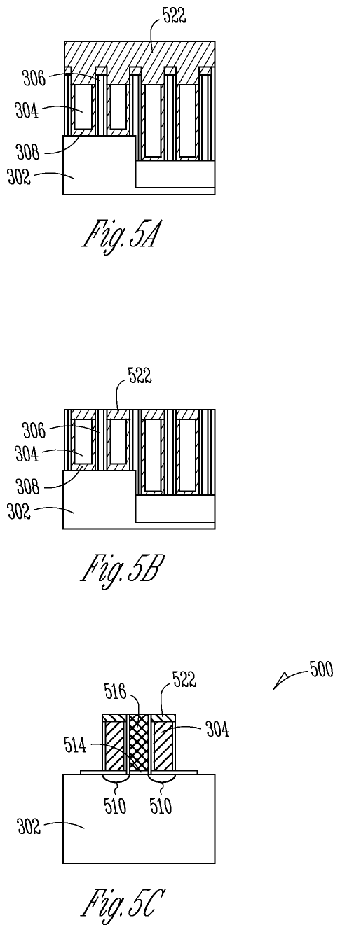

FIGS. 5A-5C show other selected stages of manufacturing of a FinFET transistor that follow the stages of manufacturing shown in FIGS. 3A-3C in another example. In FIG. 5A, a second dielectric material 522 different from the first dielectric material 304 is located within the cavities 310, over the first dielectric material 304. In one example, the second dielectric material 522 includes a nitride. In one example, the second dielectric material 522 includes silicon nitride.

FIG. 5B shows another stage of manufacture of a FinFET transistor subsequent to FIG. 5A. In FIG. 5B, the second dielectric material 522 has been planarized to a top level of the number of dummy gates 306. One example of planarization includes chemical mechanical polishing (CMP) although the invention is not so limited. In one example, the planarization in FIG. 5B is performed to stop on polysilicon from the dummy gates 306.

Similar to FIG. 4D, FIG. 5C shows a FinFET transistor 500 according to one example as formed by the manufacture stages illustrated in FIGS. 5A-5B. The polysilicon dummy gates 306 have been removed, and replaced by conductive gates 516 such as metal gates. The gates 516 are located over the fin channel 302, and are separated from the fin channel by a gate dielectric 514. A pair of source/drain regions 510 are formed on either side of the gate 516.

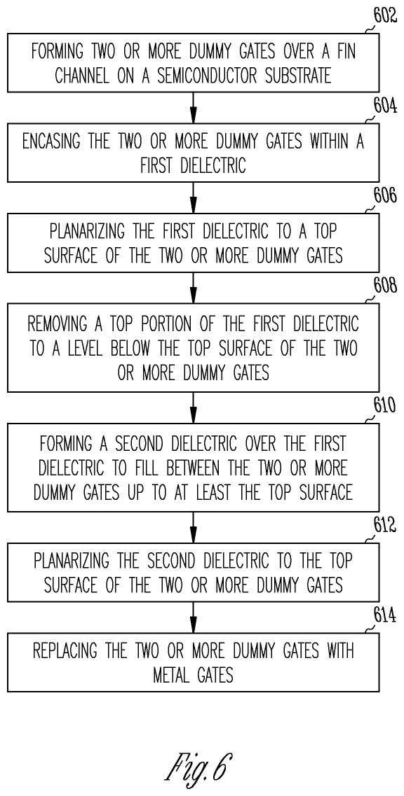

FIG. 6 shows a flow diagram of an example method of manufacture. In operation 602, two or more dummy gates are formed over a fin channel on a semiconductor substrate. In operation 604, the two or more dummy gates are encased within a first dielectric. In operation 606, the first dielectric is planarized to a top surface of the two or more dummy gates. In operation 608, a top portion of the first dielectric is removed to a level below the top surface of the two or more dummy gates. In operation 610, a second dielectric is formed over the first dielectric to fill between the two or more dummy gates up to at least the top surface. In operation 612, the second dielectric is planarized to the top surface of the two or more dummy gates. In operation 614, the two or more dummy gates are replaced with metal gates.

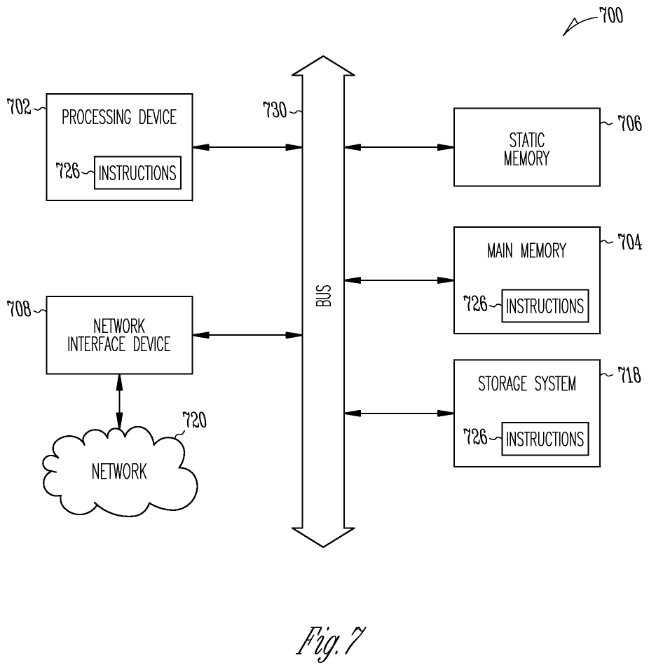

FIG. 7 illustrates a block diagram of an example machine (e.g., a host system) 1600 which may include one or more FinFETs, memory devices and/or memory systems as described above. As discussed above, machine 700 may benefit from enhanced memory performance from use of one or more of the described memory devices and/or memory systems, facilitating improved performance of machine 700 (as for many such machines or systems, efficient reading and writing of memory can facilitate improved performance of a processor or other components that machine, as described further below.

In alternative embodiments, the machine 700 may operate as a standalone device or may be connected (e.g., networked) to other machines. In a networked deployment, the machine 700 may operate in the capacity of a server machine, a client machine, or both in server-client network environments. In an example, the machine 700 may act as a peer machine in peer-to-peer (P2P) (or other distributed) network environment. The machine 700 may be a personal computer (PC), a tablet PC, a set-top box (STB), a personal digital assistant (PDA), a mobile telephone, a web appliance, an IoT device, automotive system, or any machine capable of executing instructions (sequential or otherwise) that specify actions to be taken by that machine. Further, while only a single machine is illustrated, the term “machine” shall also be taken to include any collection of machines that individually or jointly execute a set (or multiple sets) of instructions to perform any one or more of the methodologies discussed herein, such as cloud computing, software as a service (SaaS), other computer cluster configurations.

Examples, as described herein, may include, or may operate by, logic, components, devices, packages, or mechanisms. Circuitry is a collection (e.g., set) of circuits implemented in tangible entities that include hardware (e.g., simple circuits, gates, logic, etc.). Circuitry membership may be flexible over time and underlying hardware variability. Circuitries include members that may, alone or in combination, perform specific tasks when operating. In an example, hardware of the circuitry may be immutably designed to carry out a specific operation (e.g., hardwired). In an example, the hardware of the circuitry may include variably connected physical components (e.g., execution units, transistors, simple circuits, etc.) including a computer-readable medium physically modified (e.g., magnetically, electrically, moveable placement of invariant massed particles, etc.) to encode instructions of the specific operation. In connecting the physical components, the underlying electrical properties of a hardware constituent are changed, for example, from an insulator to a conductor or vice versa. The instructions enable participating hardware (e.g., the execution units or a loading mechanism) to create members of the circuitry in hardware via the variable connections to carry out portions of the specific tasks when in operation. Accordingly, the computer-readable medium is communicatively coupled to the other components of the circuitry when the device is operating. In an example, any of the physical components may be used in more than one member of more than one circuitry. For example, under operation, execution units may be used in a first circuit of a first circuitry at one point in time and reused by a second circuit in the first circuitry, or by a third circuit in a second circuitry at a different time.

The machine (e.g., computer system, a host system, etc.) 700 may include a processing device 702 (e.g., a hardware processor, a central processing unit (CPU), a graphics processing unit (GPU), a hardware processor core, or any combination thereof, etc.), a main memory 704 (e.g., read-only memory (ROM), dynamic random-access memory (DRAM) such as synchronous DRAM (SDRAM) or Rambus DRAM (RDRAM), etc.), a static memory 706 (e.g., static random-access memory (SRAM), etc.), and a storage system 718, some or all of which may communicate with each other via a communication interface (e.g., a bus) 730. In one example, the main memory 704 includes one or more memory devices as described in examples above.

The processing device 702 can represent one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. The processing device 702 can also be one or more special-purpose processing devices such as an application specific integrated circuit (ASIC), a field programmable gate array (FPGA), a digital signal processor (DSP), network processor, or the like. The processing device 702 can be configured to execute instructions 726 for performing the operations and steps discussed herein. The computer system 700 can further include a network interface device 708 to communicate over a network 720.

The storage system 718 can include a machine-readable storage medium (also known as a computer-readable medium) on which is stored one or more sets of instructions 726 or software embodying any one or more of the methodologies or functions described herein. The instructions 726 can also reside, completely or at least partially, within the main memory 704 or within the processing device 702 during execution thereof by the computer system 700, the main memory 704 and the processing device 702 also constituting machine-readable storage media.

The term “machine-readable storage medium” should be taken to include a single medium or multiple media that store the one or more sets of instructions, or any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media. In an example, a massed machine-readable medium comprises a machine-readable medium with multiple particles having invariant (e.g., rest) mass. Accordingly, massed machine-readable media are not transitory propagating signals. Specific examples of massed machine-readable media may include: non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; and CD-ROM and DVD-ROM disks.

The machine 700 may further include a display unit, an alphanumeric input device (e.g., a keyboard), and a user interface (UI) navigation device (e.g., a mouse). In an example, one or more of the display unit, the input device, or the UI navigation device may be a touch screen display. The machine a signal generation device (e.g., a speaker), or one or more sensors, such as a global positioning system (GPS) sensor, compass, accelerometer, or one or more other sensor. The machine 700 may include an output controller, such as a serial (e.g., universal serial bus (USB), parallel, or other wired or wireless (e.g., infrared (IR), near field communication (NFC), etc.) connection to communicate or control one or more peripheral devices (e.g., a printer, card reader, etc.).

The instructions 726 (e.g., software, programs, an operating system (OS), etc.) or other data are stored on the storage system 718 can be accessed by the main memory 704 for use by the processing device 702. The main memory 704 (e.g., DRAM) is typically fast, but volatile, and thus a different type of storage than the storage system 718 (e.g., an SSD), which is suitable for long-term storage, including while in an “off” condition. The instructions 726 or data in use by a user or the machine 700 are typically loaded in the main memory 704 for use by the processing device 702. When the main memory 704 is full, virtual space from the storage system 718 can be allocated to supplement the main memory 704; however, because the storage system 718 device is typically slower than the main memory 704, and write speeds are typically at least twice as slow as read speeds, use of virtual memory can greatly reduce user experience due to storage system latency (in contrast to the main memory 704, e.g., DRAM). Further, use of the storage system 718 for virtual memory can greatly reduce the usable lifespan of the storage system 718.

The instructions 724 may further be transmitted or received over a network 720 using a transmission medium via the network interface device 708 utilizing any one of a number of transfer protocols (e.g., frame relay, internet protocol (IP), transmission control protocol (TCP), user datagram protocol (UDP), hypertext transfer protocol (HTTP), etc.). Example communication networks may include a local area network (LAN), a wide area network (WAN), a packet data network (e.g., the Internet), mobile telephone networks (e.g., cellular networks), Plain Old Telephone (POTS) networks, and wireless data networks (e.g., Institute of Electrical and Electronics Engineers (IEEE) 802.15 family of standards known as Wi-Fi®, IEEE 802.16 family of standards known as WiMax®), IEEE 802.15.4 family of standards, peer-to-peer (P2P) networks, among others. In an example, the network interface device 708 may include one or more physical jacks (e.g., Ethernet, coaxial, or phone jacks) or one or more antennas to connect to the network 720. In an example, the network interface device 708 may include multiple antennas to wirelessly communicate using at least one of single-input multiple-output (SIMO), multiple-input multiple-output (MIMO), or multiple-input single-output (MISO) techniques. The term “transmission medium” shall be taken to include any intangible medium that is capable of storing, encoding, or carrying instructions for execution by the machine 700, and includes digital or analog communications signals or other intangible medium to facilitate communication of such software.

The above detailed description includes references to the accompanying drawings, which form a part of the detailed description. The drawings show, by way of illustration, specific embodiments in which the invention can be practiced. These embodiments are also referred to herein as “examples”. Such examples can include elements in addition to those shown or described. However, the present inventor also contemplates examples in which only those elements shown or described are provided. Moreover, the present inventor also contemplates examples using any combination or permutation of those elements shown or described (or one or more aspects thereof), either with respect to a particular example (or one or more aspects thereof), or with respect to other examples (or one or more aspects thereof) shown or described herein.

All publications, patents, and patent documents referred to in this document are incorporated by reference herein in their entirety, as though individually incorporated by reference. In the event of inconsistent usages between this document and those documents so incorporated by reference, the usage in the incorporated reference(s) should be considered supplementary to that of this document; for irreconcilable inconsistencies, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In the appended claims, the terms “including” and “in which” are used as the plain-English equivalents of the respective terms “comprising” and “wherein”. Also, in the following claims, the terms “including” and “comprising” are open-ended, that is, a system, device, article, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

In various examples, the components, controllers, processors, units, engines, or tables described herein can include, among other things, physical circuitry or firmware stored on a physical device. As used herein, “processor” means any type of computational circuit such as, but not limited to, a microprocessor, a microcontroller, a graphics processor, a digital signal processor (DSP), or any other type of processor or processing circuit, including a group of processors or multi-core devices.

The term “horizontal” as used in this document is defined as a plane parallel to the conventional plane or surface of a substrate, such as that underlying a wafer or die, regardless of the actual orientation of the substrate at any point in time. The term “vertical” refers to a direction perpendicular to the horizontal as defined above. Prepositions, such as “on,” “over,” and “under” are defined with respect to the conventional plane or surface being on the top or exposed surface of the substrate, regardless of the orientation of the substrate; and while “on” is intended to suggest a direct contact of one structure relative to another structure which it lies “on” (in the absence of an express indication to the contrary); the terms “over” and “under” are expressly intended to identify a relative placement of structures (or layers, features, etc.), which expressly includes—but is not limited to—direct contact between the identified structures unless specifically identified as such. Similarly, the terms “over” and “under” are not limited to horizontal orientations, as a structure may be “over” a referenced structure if it is, at some point in time, an outermost portion of the construction under discussion, even if such structure extends vertically relative to the referenced structure, rather than in a horizontal orientation.

The terms “wafer” is used herein to refer generally to any structure on which integrated circuits are formed, and also to such structures during various stages of integrated circuit fabrication. The term “substrate” is used to refer to either a wafer, or other structures which support or connect to other components, such as memory die or portions thereof. Thus, the term “substrate” embraces, for example, circuit or “PC” boards, interposers, and other organic or non-organic supporting structures (which in some cases may also contain active or passive components). The following detailed description is, therefore, not to be taken in a limiting sense, and the scope of the various embodiments is defined only by the appended claims, along with the full scope of equivalents to which such claims are entitled.

It will be understood that when an element is referred to as being “on,” “connected to” or “coupled with” another element, it can be directly on, connected, or coupled with the other element or intervening elements may be present. In contrast, when an element is referred to as being “directly on,” “directly connected to” or “directly coupled with” another element, there are no intervening elements or layers present. If two elements are shown in the drawings with a line connecting them, the two elements can be either be coupled, or directly coupled, unless otherwise indicated.

Method examples described herein can be machine or computer-implemented at least in part. Some examples can include a computer-readable medium or machine-readable medium encoded with instructions operable to configure an electronic device to perform methods as described in the above examples. An implementation of such methods can include code, such as microcode, assembly language code, a higher-level language code, or the like. Such code can include computer-readable instructions for performing various methods. The code may form portions of computer program products. Further, the code can be tangibly stored on one or more volatile or non-volatile tangible computer-readable media, such as during execution or at other times. Examples of these tangible computer-readable media can include, but are not limited to, hard disks, removable magnetic disks, removable optical disks (e.g., compact disks and digital video disks), magnetic cassettes, memory cards or sticks, random access memories (RAMS), read only memories (ROMs), and the like.

To better illustrate the method and apparatuses disclosed herein, a non-limiting list of embodiments is provided here:
Example 1 is a memory device. The memory device includes a fin channel on a semiconductor substrate. The memory device also includes a number of gates over the fin channel, the number of gates separated from the fins by one or more gate dielectrics, and an inter-gate dielectric structure between adjacent gates, wherein the inter-gate dielectric structure includes a first dielectric material adjacent the fin channel, and a second dielectric material different from the first dielectric material located over the first dielectric material.
In Example 2, the memory device of Example 1 optionally includes wherein the first dielectric material and the second dielectric material include different chemistry.
In Example 3, the memory device of any one of Examples 1-2 optionally includes wherein the first dielectric material and the second dielectric material include different densities.
In Example 4, the memory device of any one of Examples 1-3 optionally includes wherein the first dielectric material includes an oxide, and wherein the second dielectric material includes a nitride.
In Example 5, the memory device of any one of Examples 1-4 optionally includes wherein the gate dielectrics are further layered on sides of the gates.
In Example 6, the memory device of any one of Examples 1-5 optionally includes wherein silicon nitride is further layered on sides of the gates over the gate dielectrics.
In Example 7, the memory device of any one of Examples 1-6 optionally includes wherein the number of gates include metal gates.
Example 8 is a computing system. The computing system includes one or more processing cores, and a DRAM memory coupled to the one or more processing cores. The DRAM memory includes an array of memory cells, including a fin channel on a semiconductor substrate, a number of gates over the fin channel, the number of gates separated from the fins by one or more gate dielectrics, and an inter-gate dielectric structure between adjacent gates, wherein the inter-gate dielectric structure includes a first dielectric material adjacent the fin channel, and a second dielectric material different from the first dielectric material located over the first dielectric material.
In Example 9, the computing system of Example 8 optionally includes wherein the second dielectric material include includes silicon nitride.
In Example 10, the computing system of any one of Examples 8-9 optionally includes wherein the second dielectric material includes a higher density than the first dielectric material.
In Example 11, the computing system of any one of Examples 8-10 optionally includes wherein the first dielectric material includes silicon oxide, and wherein the second dielectric material includes a silicon nitride.
In Example 12, the computing system of any one of Examples 8-11 optionally further includes a network interface device coupled to the one or more processing cores.
In Example 13, the computing system of any one of Examples 8-12 optionally includes wherein the network interface device includes one or more antennae.
In Example 14, the computing system of any one of Examples 8-13 optionally includes wherein the number of gates include metal gates.
Example 15 is a method. The method includes forming two or more dummy gates over a fin channel on a semiconductor substrate, encasing the two or more dummy gates within a first dielectric, planarizing the first dielectric to a top surface of the two or more dummy gates, removing a top portion of the first dielectric to a level below the top surface of the two or more dummy gates, forming a second dielectric over the first dielectric to fill between the two or more dummy gates up to at least the top surface, planarizing the second dielectric to the top surface of the two or more dummy gates, and replacing the two or more dummy gates with metal gates.
In Example 16, the method of Example 15 optionally includes wherein forming two or more dummy gates includes forming two or more polysilicon gates.
In Example 17, the method of any one of Examples 15-16 optionally includes wherein encasing the two or more dummy gates within a first dielectric includes encasing the two or more dummy gates using a spin on glass process.
In Example 18, the method of any one of Examples 15-17 optionally includes wherein forming the second dielectric over the first dielectric includes forming the second dielectric using high density plasma deposition of silicon oxide.
In Example 19, the method of any one of Examples 15-18 optionally includes wherein forming the second dielectric over the first dielectric includes forming silicon nitride over the first dielectric.
In Example 20, the method of any one of Examples 15-19 optionally includes wherein planarizing the second dielectric to the top surface of the two or more dummy gates includes chemical mechanical polishing with a polysilicon stop setting.

The above description is intended to be illustrative, and not restrictive. For example, the above-described examples (or one or more aspects thereof) may be used in combination with each other. Other embodiments can be used, such as by one of ordinary skill in the art upon reviewing the above description. The Abstract is provided to comply with 37 C.F.R. § 1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description, with each claim standing on its own as a separate embodiment, and it is contemplated that such embodiments can be combined with each other in various combinations or permutations. The scope of the invention should be determined with reference to the appended claims, along with the full scope of equivalents to which such claims are entitled.

What is claimed is:

1. A memory device, comprising:
a fin channel on a semiconductor substrate;
a number of gates over the fin channel, the number of gates separated from the fins by one or more gate dielectrics; and
an inter-gate dielectric structure between adjacent gates, wherein the inter-gate dielectric structure includes a first dielectric material adjacent the fin channel, and a second dielectric material different from the first dielectric material located over the first dielectric material.

2. The memory device of claim 1, wherein the first dielectric material and the second dielectric material include different chemistry.

3. The memory device of claim 1, wherein the first dielectric material and the second dielectric material include different densities.

4. The memory device of claim 1, wherein the first dielectric material includes an oxide, and wherein the second dielectric material includes a nitride.

5. The memory device of claim 1, wherein the gate dielectrics are further layered on sides of the gates.

6. The memory device of claim 1, wherein silicon nitride is further layered on sides of the gates over the gate dielectrics.

7. The memory device of claim 1, wherein the number of gates include metal gates.

8. A computing system, comprising:
one or more processing cores;
a DRAM memory coupled to the one or more processing cores, the DRAM memory including;
an array of memory cells, including;
a fin channel on a semiconductor substrate;
a number of gates over the fin channel, the number of gates separated from the fins by one or more gate dielectrics; and
an inter-gate dielectric structure between adjacent gates, wherein the inter-gate dielectric structure includes a first dielectric material adjacent the fin channel, and a second dielectric material different from the first dielectric material located over the first dielectric material.

9. The computing system of claim 8, wherein the second dielectric material include includes silicon nitride.

10. The computing system of claim 8, wherein the second dielectric material includes a higher density than the first dielectric material.

11. The computing system of claim 8, wherein the first dielectric material includes silicon oxide, and wherein the second dielectric material includes a silicon nitride.

12. The computing system of claim 8, further including a network interface device coupled to the one or more processing cores.

13. The computing system of claim 12, wherein the network interface device includes one or more antennae.

14. The computing system of claim 8, wherein the number of gates include metal gates.

15. A method comprising:
forming two or more dummy gates over a fin channel on a semiconductor substrate;
encasing the two or more dummy gates within a first dielectric;
planarizing the first dielectric to a top surface of the two or more dummy gates;
removing a top portion of the first dielectric to a level below the top surface of the two or more dummy gates;
forming a second dielectric over the first dielectric to fill between the two or more dummy gates up to at least the top surface;
planarizing the second dielectric to the top surface of the two or more dummy gates; and
replacing the two or more dummy gates with metal gates.

16. The method of claim 15, wherein forming two or more dummy gates includes forming two or more polysilicon gates.

17. The method of claim 15, wherein encasing the two or more dummy gates within a first dielectric includes encasing the two or more dummy gates using a spin on glass process.

18. The method of claim 17, wherein forming the second dielectric over the first dielectric includes forming the second dielectric using high density plasma deposition of silicon oxide.

19. The method of claim 15, wherein forming the second dielectric over the first dielectric includes forming silicon nitride over the first dielectric.

20. The method of claim 15, wherein planarizing the second dielectric to the top surface of the two or more dummy gates includes chemical mechanical polishing with a polysilicon stop setting.
